(19) United States
(12) Patent Application Publication
(10) Pub. No.: US 2014/0150849 A1
(43) Pub. Date: Jun. 5, 2014

(54) PHOTOVOLTAIC CELL AND METHOD OF PRODUCTION THEREOF

(71) Applicant: DEUTSCHE CELL GMBH, Freiberg (DE)

(72) Inventor: Frederick Bamberg, Freiberg (DE)

(73) Assignee: DEUTSCHE CELL GMBH, Freiberg (DE)

(21) Appl. No.: 13/689,824

(22) Filed: Nov. 30, 2012

(51) Int. Cl. H01L 31/02; H01L 31/042

(52) U.S. Cl. CPC H01L 31/02002; H01L 31/042
USPC 136/249; 438/98; 136/256

(57) ABSTRACT

The present invention relates to a method of forming a metal layer on the surface of a photovoltaic cell by forming a first layer of a first composition on the surface of a silicon substrate and then forming a second layer of a second composition on the first layer, wherein both layers are in electrical contact with each other, the first composition comprises particles comprising or consisting of (i) B, Al, Ga, In, and/or Tl or (ii) P, As, Sb, and/or Bi, the second composition comprises metal particles, and wherein the particles of the first layer have a mean diameter smaller than the mean diameter of the metal particles of the second composition. Further, the present invention also relates to photovoltaic cells and solar modules obtainable using the method of the present invention.

### FIELD OF THE INVENTION

The present invention relates to a method of forming a metal layer on the surface of a silicon substrate by forming a first layer of a first composition comprising particles comprising or consisting of (i) a metal and/or B or (ii) N, P, and/or Sb on the silicon substrate surface and then forming a second layer of a second composition comprising particles comprising or consisting of (i) a metal and/or B or (ii) N, P, and/or Sb on the first layer, wherein the first composition comprises particles having a mean diameter smaller than the mean diameter of the metal particles of the second composition. Further, the present invention also relates to photovoltaic cells and solar modules obtainable using the method of the present invention.

### BACKGROUND OF THE INVENTION

Upon light exposure electron-hole pairs are generated in a p-n junction photovoltaic cell. The electrons and holes are separated towards their respective n-doped and p-doped regions by the electric field of the depletion region. To increase the performance of the photovoltaic cell, it is important to avoid losses that occur via, for example, surface recombination of the charge carriers. Lowering the high top surface recombination is typically accomplished by forming a passivating layer (usually silicon nitride) on the top surface. A similar effect is employed at the rear surface to minimize the impact of rear surface recombination. A “back surface field” (BSF) consists of a higher doped region of the same charge at the base-metal contact on the rear of a solar cell. The interface p++-p+ or n++-n+ between the high and low doped regions behaves like a p-n junction and an electric field forms at the interface which introduces a barrier to minority carrier flow to the rear surface. The minority carrier concentration is thus maintained at higher levels in the less doped region and the BSF has a net effect of passivating the rear surface. Further, opposite charges are directed in their movement towards the p-n junction at the cell's front side.

In Si solar cells the BSF can be formed by metallization of the rear surface, for example with aluminum, with the metal atoms diffusing into the underlying layer and resulting in a higher doped region close to the rear surface. At the same time, the aluminum layer functions as the back side contact.

Commonly, the aluminum is printed in form of a paste containing aluminum particles on the rear surface of the solar cell and annealed at high temperatures. The aluminum pastes available for these purposes comprise aluminum particles of varying diameters which are essentially polydisperse to achieve high package densities and thus better lateral conductivity.

While for good electrical conductivity larger particles and high package densities are desirable, the generation of the BSF is more efficient if smaller particles are used. Consequently, the use of the available pastes with metal particles of varying diameters represents a compromise between high electrical conductivity and good contacting/doping properties.

Hence, there exists need in the art for methods and compositions that overcome the known drawbacks of existing techniques. The present invention provides such methods.

### SUMMARY OF THE INVENTION

The objective of the present invention is to provide a method for generating a metal layer on the surface of a substrate and a device comprising such a substrate. The present invention is based on the inventor's finding that forming a layer on the surface of a photovoltaic cell by forming two separate particle-containing layers, wherein the first layer formed directly on the photovoltaic cell surface, in particular in contact regions in case a discontinuous dielectric layer is located between the metal contact and the doped substrate, comprises particles comprising or consisting of (i) a metal and/or B or (ii) P and/or Sb with a smaller mean diameter than the metal particles of the second layer formed on top of the first layer, provides for a photovoltaic cell with a backside metallization exhibiting a strong back surface field (BSF) and high electrical conductivity.

In a first aspect the present invention thus relates to a method of forming a layer on a silicon substrate, the method comprising:
(i) forming a first layer of a first composition on the surface of the silicon substrate; and
(ii) forming a second layer of a second composition on the first layer;
   wherein both layers are in electrical contact with each other, the first composition comprises particles comprising or consisting of (i) B, Al, Ga, In, and/or Tl or (ii) P, As, Sb, and/or Bi, the second composition comprises metal particles, and wherein the particles of the first layer have a mean diameter smaller than the mean diameter of the metal particles of the second composition.

In another aspect the present invention relates to a photovoltaic cell which is manufactured or obtainable according to the method of the present invention.

In still another aspect, the present invention is directed to a photovoltaic cell comprising a rear surface metal layer, wherein the metal layer comprises a first layer and a second layer, wherein the first layer comprise particles comprising or consisting of (i) B, Al, Ga, In, and/or Tl or (ii) P, As, Sb, and/or Bi, wherein the second layer comprises metal particles, wherein the first layer is sandwiched between the silicon base layer of the photovoltaic cell and the second layer, and wherein the first layer comprises particles with a smaller mean diameter than the particles of the second layer.

In a still further aspect, the present invention relates to a solar module comprising one or more photovoltaic cells according to the invention.

### BRIEF DESCRIPTION OF THE DRAWINGS

FIG. 1 is a schematic illustration of a cross-sectional view showing a first layer 102 comprising particles 104 on the surface of a silicon substrate 103 and a second layer 101 comprising particles 105 having a greater average diameter than the particles 104 of the first layer 102, whereby the second layer 101 is deposited on top of the first layer 102 and the two layers are in electrical contact with each other.

FIG. 2 is a schematic illustration of a cross-sectional view wherein the first layer 202 comprise particles deposited on the silicon substrate 203 is discontinuous and covered by the second layer 201 comprising particles. The particles of the first layer 202 have a smaller average diameter than the particles of the second layer 201.

FIG. 3 is a schematic illustration of a cross-sectional view, wherein between the second layer 301 and the silicon substrate 303 a first layer 304 and another layer, such as a passivating layer, 302, are disposed.

FIG. 4 is a schematic illustration of a cross-sectional view, wherein between the second layer 401 and the silicon substrate 403 a first layer 404 and another layer, such as a passivating layer, 402, are disposed.

### DETAILED DESCRIPTION OF THE INVENTION

The present invention is based on the inventor's surprising finding that by generating the metal layer at the rear surface of a photovoltaic cell in a two-step process including forming two separate layers that differ with respect to the particle size, the conductivity of the backside metallization as well as the back surface field and the electric field of the photovoltaic cell can be improved. Without wishing to be bound to a particular theory, it is believed that this improvement is due to a first layer comprising particles with a small mean diameter that allow a better contacting and doping of the underlying silicon layer and a second layer with larger particles that provide for an improved electrical conductivity. Accordingly, the present invention allows for high BSF strength and high conductivity by avoiding the limitations imposed by using only one metal-containing paste for the rear surface metallization.

Based on this finding, the present invention thus relates to a method of forming a contact layer on the surface of a silicon substrate, such as a photovoltaic cell, including the steps of:
(i) forming a first layer of a first composition on the surface of substrate; and
(ii) forming a second layer of a second composition on the first layer,
   wherein both layers are in electrical contact with each other, wherein the first composition comprises particles comprising or consisting of (i) B, Al, Ga, In, and/or Tl or (ii) P, As, Sb, and/or Bi, wherein the second composition comprises particles comprising or consisting of a metal, and wherein the particles of the first layer have an median diameter smaller than the median diameter of the metal particles of the second composition.

The particles of the first layer are selected from the same group of elements, i.e. either (i) B, Al, Ga, In, and/or Tl or (ii) P, As, Sb, and/or Bi. The type of element comprised in the particles depends on whether the silicon layer is a p-type silicon layer, in which case the element is selected from the first group, or an n-type silicon layer, in which case the element is selected from the second group.

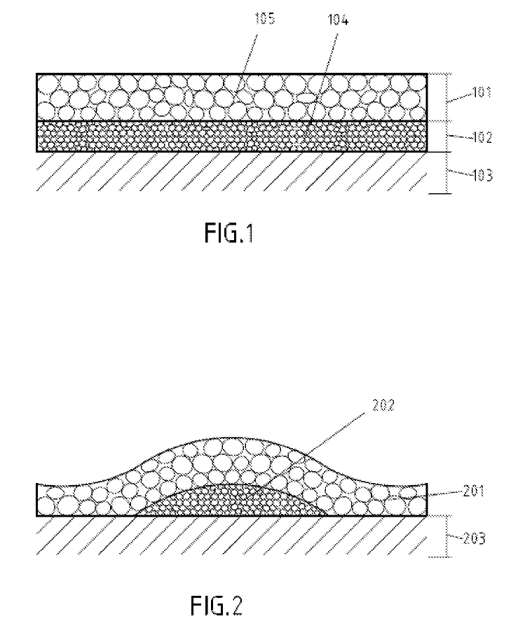

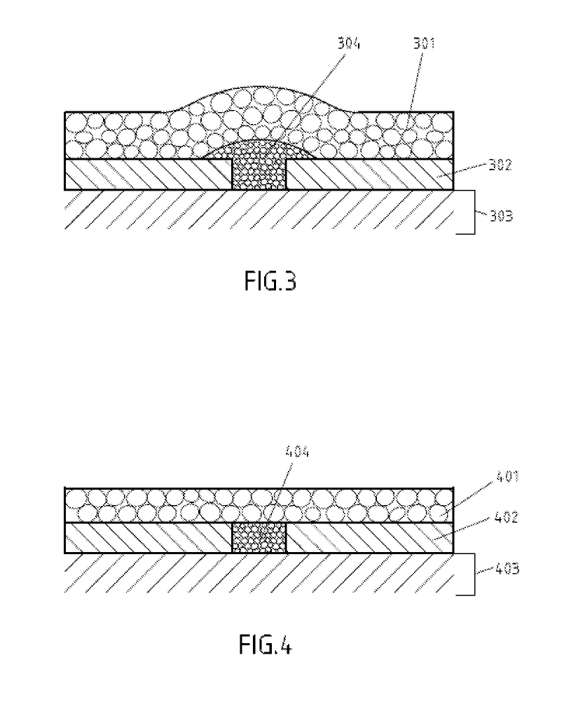

The step of forming the second layer on the first layer means that the two layers are, at least partially in contact with each other. Accordingly, the first, the second or both layers may be discontinuous. It is also contemplated that another layer is disposed between the first and second layer such that the first and second layer are only in certain regions in contact with each other. In one embodiment, the first layer is only formed in certain areas of the substrate while in other surface areas of the substrate another different layer, such as a passivating layer, is formed, and the second layer is formed on top of both, for example such that is does not directly contact the substrate surface. Exemplary arrangements of the two layers on the substrate are schematically illustrated in FIGS. 1-4.

The layer formed on the surface of the silicon substrate thus consists of at least two separate layers, one layer with finer particles, termed first layer, which contacts the underlying silicon layer at least partially. This layer can contact the underlying layer in small regions, for example in spot-like regions, which can be isolated from or connected to each other, or can contact the underlying layer over larger parts and form widespread layers. The second layer is disposed on top of this fine particle layer and comprises larger metal particles, with this layer being term second layer. The second layer can be formed directly on top of the first layer, but, as described above, it is also contemplated that there are one or more additional layers formed between the first and second layer. Similarly, it is also encompassed by the present invention that the contact layer on the surface of the photovoltaic cells comprises more than the two layers, i.e. the first and second layer. Accordingly, the method of the invention can further comprise the step(s) of forming a third, fourth, etc. layer on top of the second layer.

The formation of the layers can be done by various techniques known to those skilled in the art and includes, without being limited thereto, printing, plating, such as plating deposition, dip-coating, spray-coating, powder-coating and/or vapor deposition, including chemical vapor deposition (CVD) and physical vapour deposition (PVD). The printing may, for example, be screen-printing or extrusion-printing.

Generally, the compositions used for the formation of the layers are in a form that allows the formation of the layer by the selected technique. This means that the compositions may be in form of a powder, a liquid or in gaseous form. The term “liquid”, as used in this context, includes dispersions, gels and pastes.

The layers formed may be electrically conductive.

In one embodiment of the present invention the particles comprised in the first composition may be selected from aluminum (Al), boron (B), gallium (Ga), indium (In), thallium (Tl) and/or combinations thereof, preferably Al or B, more preferably Al. In another embodiment, the particles comprised in the first composition may be selected from phosphorous (P), arsenic (As), bismuth (Bi) and/or combinations thereof, preferably P.

In various embodiments, the particles of the second composition can comprise or consist of metals that are electrically conductive, such as aluminum (Al), silver (Ag) or copper (Cu). Alternatively, independent from the particles of the first composition, the metal particles comprised in the second composition may be selected from any metal listed above as a component of the first composition, i.e. from aluminum (Al), gallium (Ga), indium (In), thallium (Tl) and/or combinations thereof, preferably Al, or, alternatively be bismuth (Bi). In a further alternative, the particles of the second composition can be selected from any electrically conductive metal.

Generally, the particles may be substantially monodisperse. This means that their diameter varies only up to about 50, or up to about 100% from the mean diameter. “Monodisperse”, as used herein, thus can mean that about 90% of the particles contained in the composition have a diameter that lies within the range of the mean diameter lies within the range of the mean diameter ±100% or the range of the mean diameter ±50%.

Alternatively, in other embodiments, the particles may be polydisperse.

The term “diameter”, as used herein in connection with the particles, relates to the diameter in the largest dimension of the particles if they are not spherical.

In various embodiments, the particles of the first composition can have a mean diameter <5 μm, for example <3 μm, or it is in the range of about 0.01 μm to about 5 μm, about 0.02 μm to about 4 μm, or about 0.03 μm to about 3 μm. The metal particles of the second composition may have a mean diameter of about 0.1 μm to about 20 μm, about 1 μm to about 15 μm, or about 3 μm to about 10 μm.

The particles described in the present invention can have any shape, including but not limited to spherical, cubic, rectangular, needle-like, fibrous, flake-like, rhombic, and pyramidal. Preferred shapes include spherical, cubic, rectangular, rhombic, and flake-like.

The two layers may have the same of different thicknesses. In various embodiments, the mean thickness of the first layer is smaller than the mean thickness of the second layer. For example, the mean thickness of the first layer can be <20 μm, for example <10, <5 or <1 μm, or can be in the range of between about 0.1 μm to about 20 μm, about 0.5 μm to about 15 μm, about 1 μm to about 10 μm, or about 1 μm to about 5 μm. The mean thickness of the second layer can, in various embodiments, be in the range of between about 2 μm to about 70 μm, about 3 μm to about 40 μm, or about 5 μm to about 30 μm.

The inventive method can further comprise additional steps, including but not limited to drying steps carried out after forming the first layer, for example by screen-printing a particle-containing paste and drying it before forming the second layer. Similarly, a drying step may also be carried out once the second layer has been formed. In addition, after forming the first layer and/or the second layer a heating step or a sintering step (“firing”) may be carried out. The drying step can also be carried out at elevated temperature between 100-300° C., for example at around 200° C. The sintering step may be performed at a temperature in the range of about 400 to 1000° C., or about 550-850° C.

The compositions used for forming the layer may comprise, in addition to the above-defined particles, one or more additional components. Exemplary components that are used in such compositions include, but are not limited to solvents, dispersing agents, additives, rheology adjusting agents, fillers, glasses, and mixtures thereof. Also possible is that it contains other metal that are used to influence the electrical conductivity of the formed layer. As mentioned above, the compositions can be in form of a paste. In various embodiments, the compositions are in form of a printable, preferably screen-printable, paste.

The layer formed on the surface of the photovoltaic cell may be a coating. This means that it covers the entire surface. Alternatively, it can only cover parts of the surface, for example in contact regions.

In various embodiments, the silicon substrate is a silicon photovoltaic cell. In one specific embodiment, the surface on which the layer is formed is the surface of the p-type layer of a Si photovoltaic cell. The surface may be the rear surface, i.e. the surface not exposed to light upon use.

The present invention also relates to a photovoltaic cell that is obtainable or obtained by practicing the above-described method.

Generally, the present invention is also directed to photovoltaic cells comprising a rear surface metal layer, the rear surface metal layer comprising a first layer and a second layer, the first layer comprising particles comprising or consisting of (i) B, Al, Ga, In, and/or Tl or (ii) P, As, Sb, and/or Bi, the second layer comprising particles comprising or consisting of any metal, for example Al, Ag or Cu, and the first layer being sandwiched between the silicon base layer of the photovoltaic cell and the second layer, wherein the first layer comprises particles with a smaller mean diameter than the metal particles of the second layer.

In such a photovoltaic cell, one or both of the layers can be in electrical contact with each other.

The particles of the first layer and the particles of the second layer are with respect to their sizes, dispersities, and materials defined as described above in connection with the particles of the first and second composition. Again, the photovoltaic cell may comprise more than the two layers defined above.

Similarly, the thicknesses of the layers of the photovoltaic cell are defined similar to those disclosed above in connection with the inventive method. Nevertheless, the thickness of the layers as disclosed above may be further reduced by shrinkage that has occurred during a drying or sintering step.

The layer may have the form of a coating.

Finally, the present invention also features a solar module comprising one or more photovoltaic cells according to the invention.

While particular preferred and alternative embodiments of the present intention have been disclosed, it will be apparent to one of ordinary skill in the art that many various modifications and extensions of the above described technology may be implemented using the teaching of this invention described herein. All such modifications and extensions are intended to be included within the true spirit and scope of the invention as discussed in the appended claims.

1. A method of forming a layer on the surface of a silicon substrate, the method comprising:
(i) forming a first layer of a first composition on the surface of the silicon substrate; and
(ii) forming a second layer of a second composition on the first layer;
wherein both layers are in electrical contact with each other, the first composition comprises particles comprising or consisting of (i) B, Al, Ga, and/or Tl or (ii) P, As, Sb, and/or Bi, the second composition comprises particles comprising or consisting of a metal, and wherein the particles of the first layer have a mean diameter smaller than the mean diameter of the metal particles of the second composition.

2. The method according to claim 1, wherein the first layer and/or the second layer are formed by screen printing, extrusion printing, and/or plating deposition the first composition and/or the second composition onto the silicon substrate.

3. The method according to claim 1, wherein the particles of the first composition comprise (i) B and/or Al or (ii) P and/or Sb; and/or wherein the particles of the second composition comprise an electrically conductive metal, preferably Al.

4. The method according to claim 1, wherein the particles of the first composition and/or the metal particles of the second composition are substantially monodisperse.

5. The method according to claim 1, wherein the mean thickness of the first layer is smaller than the mean thickness of the second layer.

6. The method according to claim 1, wherein the first composition and/or the second composition further comprise at least one component selected from the group consisting of solvents, dispersing agents, additives, rheology adjusting agents, fillers, glasses, and mixtures thereof.

7. The method according to claim 1, wherein the silicon substrate is a photovoltaic cell.

8. A photovoltaic cell obtainable according to the method of claim 1.

9. Photovoltaic cell comprising a back surface metal layer, the back surface metal layer comprising a first layer and a second layer, the first layer comprising particles comprising or consisting of (i) B, Al, Ga, and/or Tl or (ii) P, As, Sb, and/or Bi, the second layer comprising metal particles, and the first layer being sandwiched between a silicon substrate of the photovoltaic cell and the second layer, wherein the first layer comprises particles with a smaller mean diameter than the metal particles of the second layer.

10. The photovoltaic cell according to claim 9, wherein the particles of the first layer and/or the metal particles of the second layer are substantially monodisperse.

11. The photovoltaic cell according to claim 9, wherein the mean thickness of the first layer is smaller than the mean thickness of the second layer.

12. The photovoltaic cell according to claim 9, wherein the thickness of the first layer is in the range of between about 0.1 μm-20 μm.

13. The photovoltaic cell according to claim 9, wherein the thickness of the second layer is in the range of between about 2 μm-70 μm.

14. The photovoltaic cell according to claim 9, wherein the particles of the first layer have a mean diameter of about 0.01 μm to about 5 μm.

15. The photovoltaic cell according to claim 9, wherein the metal particles of the second layer have a mean diameter of about 0.1 μm to about 20 μm.

16. A solar module comprising one or more photovoltaic cells according to claim 9.

17. The photovoltaic cell according to claim 9, wherein the thickness of the first layer is in the range of between about 0.5 μm-15 μm.

18. The photovoltaic cell according to claim 9, wherein the thickness of the first layer is in the range of between about 1 μm-10 μm.

19. The photovoltaic cell according to claim 9, wherein the thickness of the second layer is in the range of between about 3 μm-40 μm.

20. The photovoltaic cell according to claim 9, wherein the thickness of the second layer is in the range of between about 5 μm-30 μm.
